(19) United States
(12) Patent Application Publication
(10) Pub. No.: US 2026/0283019 A1
(43) Pub. Date: Sep. 17, 2026

(54) STORAGE DEVICE AND METHOD OF MANUFACTURING STORAGE DEVICE

(71) Applicant: Kioxia Corporation, Tokyo (JP)

(72) Inventor: Hideki TAKAHASHI, Yokohama Kanagawa (JP)

(21) Appl. No.: 19/323,706

(22) Filed: Sep. 9, 2025

(30) Foreign Application Priority Data
Mar. 17, 2025 (JP) 2025-042181

(51) Int. Cl. H01L 25/16; H01L 23/00; H01L 23/34; H01L 23/498; H01L 23/538; H01L 25/065; H10B 80/00

(52) U.S. Cl. CPC H10W 90/00; H10B 80/00; H10W 40/10; H10W 70/60; H10W 70/611; H10W 70/658; H10W 70/66; H10W 90/701; H10W 72/07236; H10W 72/07253; H10W 72/234; H10W 72/884; H10W 90/24; H10W 90/724; H10W 90/732; H10W 90/734; H10W 90/752; H10W 90/754

(57) ABSTRACT

According to one embodiment, a storage device includes a substrate, a first solder, a first electronic component, and a second solder. The substrate includes a first pad and a second pad. The first solder is provided on the first pad. The first electronic component is electrically connected to the first pad by the first solder. At least a part of the second solder is provided on the second pad. The second solder has a different melting point from the first solder.

### CROSS-REFERENCE TO RELATED APPLICATION

This application is based upon and claims the benefit of priority from Japanese Patent Application No. 2025-042181, filed Mar. 17, 2025, the entire contents of which are incorporated herein by reference.

### FIELD

Embodiments described herein relate generally to a storage device and a method of manufacturing the storage device.

### BACKGROUND

A storage device including a substrate that includes a pad and an electric component electrically connected to the pad is known.

### BRIEF DESCRIPTION OF THE DRAWINGS

FIG. 1 illustrates a plan view of a storage device according to a first embodiment.

FIG. 2 illustrates an enlarged plan view of a portion surrounded by F2 in the configuration illustrated in FIG. 1.

FIG. 3 illustrates a cross-sectional view taken along a line F3-F3 in the configuration illustrated in FIG. 2.

FIG. 4 is a diagram illustrating a NAND package according to the first embodiment.

FIG. 5 is a diagram illustrating a state of a wiring change unit before a high-temperature reflow according to the first embodiment.

FIG. 6 is a diagram illustrating a state of the wiring change unit after the high-temperature reflow according to the first embodiment.

FIG. 7 is a flowchart illustrating a method of manufacturing the storage device according to the first embodiment.

FIG. 8 illustrates a plan view of a storage device according to a second embodiment.

FIG. 9 illustrates an enlarged plan view of a portion surrounded by F9 in the configuration illustrated in FIG. 8.

FIG. 10 illustrates a cross-sectional view taken along a line F10-F10 in the configuration illustrated in FIG. 9.

FIG. 11 is a diagram illustrating a state of a wiring change unit before a high-temperature reflow according to the second embodiment.

FIG. 12 is a diagram illustrating a state of the wiring change unit after the high-temperature reflow according to the second embodiment.

FIG. 13 is a flowchart illustrating a method of manufacturing the storage device according to the second embodiment.

FIG. 14 illustrates a cross-sectional view of a storage device according to a third embodiment.

FIG. 15 is a flowchart illustrating a method of manufacturing the storage device according to the third embodiment.

FIG. 16 illustrates a cross-sectional view of a storage device according to a fourth embodiment.

FIG. 17 is a diagram illustrating a state of a wiring change unit after a low-temperature reflow according to the fourth embodiment.

FIG. 18 is a flowchart illustrating a method of manufacturing the storage device according to the fourth embodiment.

### DETAILED DESCRIPTION

Embodiments provide a storage device in which a connection state of a wiring is easily changeable in a state in which an electronic component is mounted.

In general, according to an embodiment, a storage device includes a substrate, a first solder, a first electronic component, and a second solder. The substrate includes a first pad and a second pad. The first solder is provided on the first pad. The first electronic component is electrically connected to the first pad by the first solder. At least a part of the second solder is provided on the second pad. The second solder has a different melting point from the first solder.

Hereinafter, a storage device and a method of manufacturing the storage device according to embodiments will be described with reference to the drawings. In the following description, identical or similar configurations with the same functions are denoted by the same reference numerals. Repeated description of such configurations may be omitted.

In the specification, terms “parallel”, “orthogonal”, or “same” may each include “substantially parallel”, “substantially orthogonal”, or “substantially the same”. A term “overlap” refers to virtual projected images of two objects overlapping each other. That is, “overlap” is not limited to two objects being in contact, and may also include two objects not being in contact (for example, a space or another member being provided between the two objects). In the specification, a term “connection” is not limited to mechanical connection and may also include electrical connection. That is, the term “connection” is not limited to direct connection to an object and may include connection to an object with another member interposed therebetween.

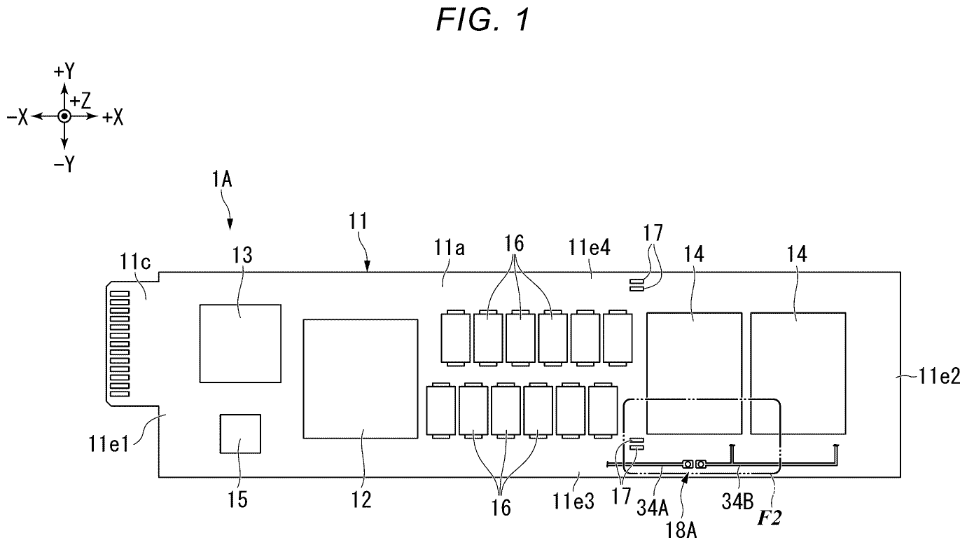

In the specification, +X, −X, +Y, −Y, +Z, and −Z directions are defined as follows. The +X, −X, +Y, and −Y directions are directions parallel to a first surface 11a of a substrate 11 to be described below (see FIG. 1). The +X direction is a direction oriented from a first end 11e1 to a second end 11e2 of the substrate 11 to be described below (see FIG. 1). The −X direction is a direction opposite to the +X direction. When the +X and −X directions are not distinguished from each other, the +X and −X directions are simply referred to as an “X direction”. The +Y and -Y directions are directions intersecting (for example, orthogonal to) the X direction. The +Y direction is a direction oriented from a third end 11e3 to a fourth end 11e4 (see FIG. 1). The −Y direction is a direction opposite to the +Y direction. When the +Y and −Y directions are not distinguished from each other, the +Y and −Y directions are simply referred to as a “Y direction”. The +Z and −Z directions are directions intersecting (for example, orthogonal to) the X and Y directions and are a thickness direction of the substrate 11. The +Z direction is a direction oriented from the substrate 11 to a controller 12 (see FIG. 1). The-Z direction is a direction opposite to the +Z direction. When the +Z and −Z directions are not distinguished from each other, the +Z and −Z directions are simply referred to as a “Z direction”.

### First Embodiment

A first embodiment is an example in which electronic components are mounted by a low-temperature reflow and a portion of wirings are in a non-conductive state and the wirings are changed from the non-conductive state to a conductive state by executing a high-temperature reflow later.

### A1. Overall Configuration of Storage Device

A storage device 1A according to the first embodiment will be described with reference to FIGS. 1 to 7. The storage device 1A is, for example, a storage device such as a solid state drive (SSD). The storage device 1A may also be referred to as a “semiconductor storage device”. The storage device 1A is fitted in a host apparatus and is used as a storage device of the host apparatus. The host apparatus is a personal computer, a mobile apparatus, a video recorder, an in-vehicle apparatus, or the like, and is not limited thereto.

FIG. 1 illustrates a plan view of the storage device 1A. The storage device 1A includes, for example, a substrate 11, a controller 12, a dynamic random access memory (DRAM) 13, a plurality of NAND flash memories 14 (hereinafter referred to as “NAND packages 14” for convenience), a power circuit component 15, a plurality of capacitors 16, a surface-mounted component 17, and a wiring change unit 18A. The storage device 1A may include a casing that accommodates the above-described substrate 11 and the like.

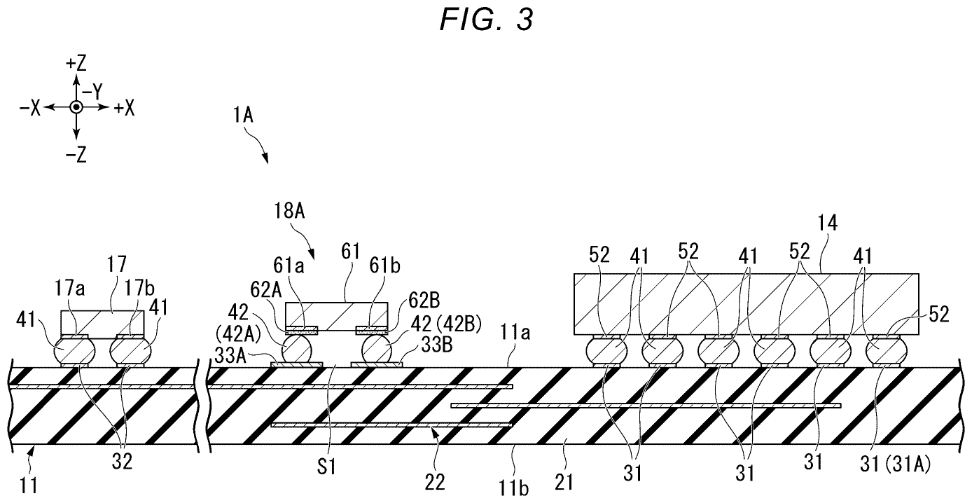

The substrate 11 is a plate member in the X and Y directions. The substrate 11 is a printed substrate, and includes an insulator base 21 and a wiring pattern 22 provided in the insulating base 21 (see FIG. 3). The substrate 11 includes a first surface 11a and a second surface 11b located on an opposite side to the first surface 11a (see FIG. 3). Each of the first surface 11a and the second surface 11b extends in the X and Y directions.

The substrate 11 includes a first end 11e1, a second end 11e2, a third end 11e3, and a fourth end 11e4. The first end 11e1 and the second end 11e2 are a pair of ends in a longitudinal direction of the substrate 11 (X direction). The third end 11e3 and the fourth end 11e4 are a pair of ends in a transverse direction of the substrate 11 (Y direction).

The first end 11e1 of the substrate 11 includes a connection connector 11c. The connection connector 11c is a connection portion that can be connected to a connector of the host apparatus. The connection connector 11c includes a plurality of metal terminals that can be connected to the connector of the host apparatus.

The controller 12 is a component that comprehensively controls the entire storage device 1A. The controller 12 is, for example, a semiconductor package that includes a system on a chip (SoC) in which a host interface circuit for the host apparatus, a control circuit controlling the DRAM 13, a control circuit controlling the plurality of NAND packages 14, and the like are integrated in one semiconductor chip. The controller 12 is provided on, for example, the first surface 11a of the substrate 11.

The DRAM 13 is a semiconductor package including a volatile semiconductor memory chip. The DRAM 13 is a data buffer that temporarily stores data to be written received from the host apparatus, read data read from the NAND package 14, and the like. The DRAM 13 is provided on, for example, the first surface 11a of the substrate 11. The DRAM 13 may be provided inside the controller 12 instead of or in addition to the above example.

The NAND package 14 is a semiconductor package including a nonvolatile semiconductor memory chip. The NAND package 14 is provided on, for example, at least one of the first surface 11a or the second surface 11b of the substrate 11. The NAND package 14 is an example of a “semiconductor memory”. Here, “semiconductor memory” is not limited to a NAND flash memory and may be another type memory such as a NOR memory, a magnetoresistive random access memory (MRAM), or a resistance-Variable

### Memory.

The power circuit component 15 supplies power to the controller 12, the DRAM 13, the plurality of NAND packages 14, the plurality of capacitors 16, and the like. The power circuit component 15 is, for example, a semiconductor package in which a plurality of power circuits necessary for supplying power to the controller 12, the DRAM 13, the NAND packages 14, and the capacitors 16 are integrated in one semiconductor chip. For example, the power circuit component 15 receives power from outside via the connection connector 11c and distributes the received power in the substrate 11.

The capacitor 16 is a component that has a power backup function for protecting data when unexpected shutdown occurs. When unexpected shutdown of power supply from the host apparatus occurs, the capacitor 16 supplies power to the controller 12, the DRAM 13, and the plurality of NAND packages 14 for a certain time.

The surface-mounted component 17 is a component that is surface-mounted on the first surface 11a or the second surface 11b of the substrate 11. The surface-mounted component 17 is, for example, a component in a circuit provided in the substrate 11. The surface-mounted component 17 is, for example, a diode, a transistor, an integrated circuit component, a resistor, a capacitor, or an inductor, but the disclosure is not limited thereto. The surface-mounted component 17 includes, for example, terminals 17a and 17b facing the substrate 11 (see FIG. 3).

The wiring change unit 18A is a functional unit that changes an electrical connection state of a part of the wiring pattern 22 as necessary. For example, the wiring change unit 18A is used to change electrical connection states of wiring lines 34A and 34B in the wiring pattern 22. For example, the wiring change unit 18A is used to change the electrical connection states of the wiring lines 34A and 34B from a non-conductive state to a conductive state.

In the present embodiment, the wiring change unit 18A is used for changing an electrical connection state of a part of the wiring pattern 22 to change a function of the storage device 1A. Hereinafter, as an example of a function of the storage device 1A, an example in which a heating function of recovering a memory cell transistor in the NAND package 14 from a deteriorated state (wear-out state) is provided will be adopted for description. Therefore, an example in which on and off of the heating function of the NAND package 14 is changed by electrically connecting the wiring change unit 18A to the NAND package 14 will be described below. Details of the heating function of the NAND package 14 is described, for example, in the specification of Japanese Patent Application No. 2023-151706. The literature is referenced in the entirety in the specification of the application.

Hereinafter, a function of the storage device 1A that can be changed by the wiring change unit 18A may be referred to as “specific function”. The specific function is not limited to the above-described heating function. For example, the specific function may be a function related to writing, reading, or erasing of data, may be a function related to protection of data, or may be a function related to power saving, temperature management, or the like. The wiring change unit 18A may be electrically connected to the controller 12, the DRAM 13, the power circuit component 15, the capacitor 16, the surface-mounted component 17, or the like instead of or in addition to electrical connection to the NAND package 14.

The wiring change unit 18A is provided on the first surface 11a or the second surface 11b of the substrate 11. The wiring change unit 18A includes, for example, a solder 42A, a solder 42B, and a jumper component 61 in addition to pads 33A and 33B provided on the surface of the substrate 11 (see FIG. 3). The wiring change unit 18A will be described in detail below. For convenience, the jumper component 61 may be referred to as “specific component”. In the specification, “specific component” means a component used to change an electrical connection state in the wiring change unit 18A. The jumper component 61 is an example of “second electronic component”.

Hereinafter, each of the controller 12, the DRAM 13, the NAND package 14, the power circuit component 15, the capacitor 16, and the surface-mounted component 17 may be referred to as “basic component”. In the specification, “basic component” means an electronic component different from “specific component”. “Basic component” is, for example, an electronic component necessary for writing, reading, or erasing of data that is a basic operation of the storage device 1A. Each of the controller 12, the DRAM 13, the NAND package 14, the power circuit component 15, the capacitor 16, and the surface-mounted component 17 is an example of “first electronic component”.

### A2. Substrate

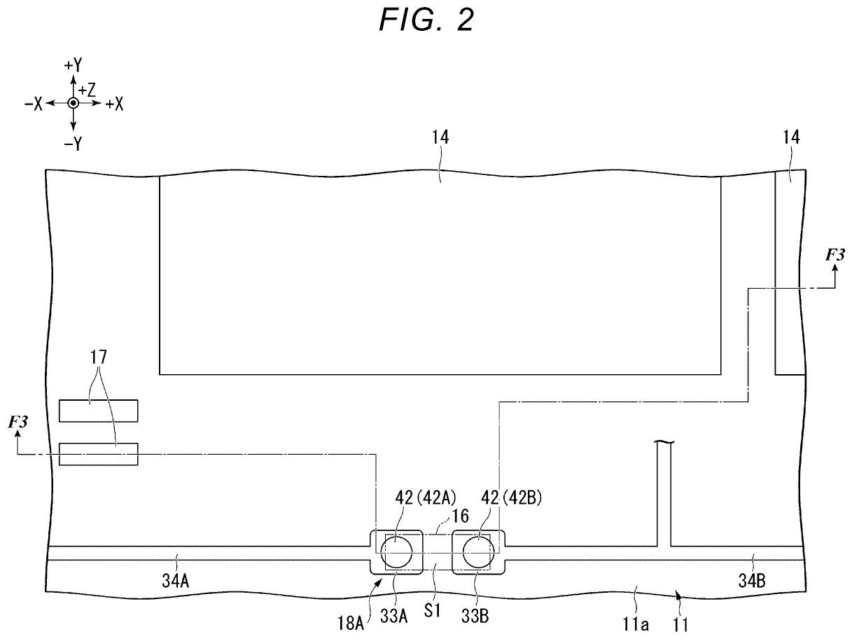

Next, a configuration of the substrate 11 will be described. FIG. 2 illustrates an enlarged plan view of a portion surrounded by F2 in the configuration illustrated in FIG. 1. FIG. 3 illustrates a cross-sectional view taken along a line F3-F3 in the configuration illustrated in FIG. 2. As described above, the substrate 11 includes the insulating base 21 and the wiring pattern 22.

The insulating base 21 is an insulating base member that forms a base of the substrate 11. The insulating base 21 is, for example, an insulating hard member formed of an insulating material such as glass epoxy or polyimide.

The wiring pattern 22 is a conductive portion provided in the insulating base 21. The wiring pattern 22 may be referred to as “conductive pattern”. The wiring pattern 22 is provided on an inner layer and a surface of the insulating base 21. The wiring pattern 22 is formed of, for example, a copper material. The wiring pattern 22 includes, for example, a plurality of pads 31, a plurality of pads 32, two pads 33A and 33B, and two wiring lines 34A and 34B (see FIG. 2).

### Pad for Basic Component

The pad 31 is a pad on which the above-described basic component is mounted. The pad 31 overlaps a basic component when viewed in the Z direction and is electrically connected to the basic component via a solder 41 to be described below. The pad 31 is provided on the first surface 11a or the second surface 11b of the substrate 11. The pad 31 is an example of “first pad”. In the example illustrated in FIG. 3, the NAND package 14 is mounted on the pad 31. That is, the pad 31 overlaps the NAND package 14 when viewed in the Z direction and is electrically connected to the NAND package 14 via the solder 41. In the present embodiment, a plurality of pads 31 on which the NAND package 14 is mounted include a pad 31A used in the specific function (for example, the heating function).

Similarly, the pad 32 is a pad on which the above-described basic component is mounted. The pad 32 overlaps the basic component when viewed in the Z direction and is electrically connected to the basic component via the solder 41. The pad 32 is provided on the first surface 11a or the second surface 11b of the substrate 11. The pad 32 is another example of “first pad”. In the example illustrated in FIG. 3, the surface-mounted component 17 is mounted on the pad 32. That is, the pad 32 overlaps the surface-mounted component 17 when viewed in the Z direction and is electrically connected to the surface-mounted component 17 via the solder 41.

In the present embodiment, the solder 41 is provided on each of the pads 31 and 32. The solder 41 is a solder that has a lower melting point than a solder 42 to be described below. The solder 41 is an example of “first solder”. Hereinafter, the solder 41 is referred to as “low-temperature solder”. The above-described basic component is physically and electrically connected to the pad 31 or 32 by the solder 41.

In the example illustrated in FIG. 3, as will be described below, a pad 52 of the NAND package 14 is electrically connected to the pad 31 of the substrate 11 by the solder 41. The solder 41 is melted once by a reflow process (a low-temperature reflow as a primary reflow to be described below) and has a shape that is wet and spread (may be referred to as “post-reflow shape”) along a surface of the pad 31. The solder 41 is in contact with at least a part of an edge of the pad 31 when viewed in the Z direction. The solder 41 is in contact with at least a part of an edge of the pad 52 of the NAND package 14 when viewed in the Z direction.

Each of terminals 17a and 17b of the surface-mounted component 17 is electrically connected to the pad 32 by the solder 41. The solder 41 is melted once by a reflow process (a low-temperature reflow as a primary reflow to be described below) and has a shape that is wet and spread along the surface of the pad 32. The solder 41 is in contact with at least a part of the edge of the pad 32 when viewed in the Z direction. The solder 41 is in contact with at least a part of an edge of the terminal 17a of the surface-mounted component 17 when viewed in the Z direction. Similarly, the solder 41 is in contact with at least a part of an edge of the terminal 17b of the surface-mounted component 17 when viewed in the Z direction.

### Pad for Specific Component

The pads 33A and 33B are a pair of pads on which the above-described specific component (for example, the jumper component 61) is mounted. The pads 33A and 33B are provided in the above-described wiring change unit 18A. For example, the pads 33A and 33B are provided on the first surface 11a or the second surface 11b of the substrate 11. The pads 33A and 33B are adjacent to each other in the X or Y direction. The pads 33A and 33B are disposed apart from each other with a gap S1 therebetween and are electrically separated from each other (that is, electrically insulated). The pad 33A is an example of “second pad”. The pad 33B is an example of “third pad”.

### Wiring Line

Next, referring back to FIG. 2, the wiring lines 34A and 34B will be described.

The wiring line 34A is a wiring line connected to the pad 33A. The wiring line 34A is connected to the pad 33A, for example, directly or through a via (not illustrated). For example, the wiring line 34A is provided between the pad 33A and the power circuit component 15 and electrically connects the pad 33A to the power circuit component 15.

Meanwhile, the wiring line 34B is a wiring line connected to the pad 33B. The wiring line 34B is connected to the pad 33B, directly or through a via (not illustrated). For example, the wiring line 34B is provided between the pad 33B and the pad 31A used in the specific function and electrically connects the pad 33B to the pad 31A.

The wiring lines 34A and 34B are disposed apart from each other and electrically separated from each other (that is, electrically insulated). Each of the wiring lines 34A and 34B is an example of “wiring”. Each of the wiring lines 34A and 34B may also be referred to as “conductive line”.

### A3. NAND Package

Next, a configuration of the NAND package 14 will be described.

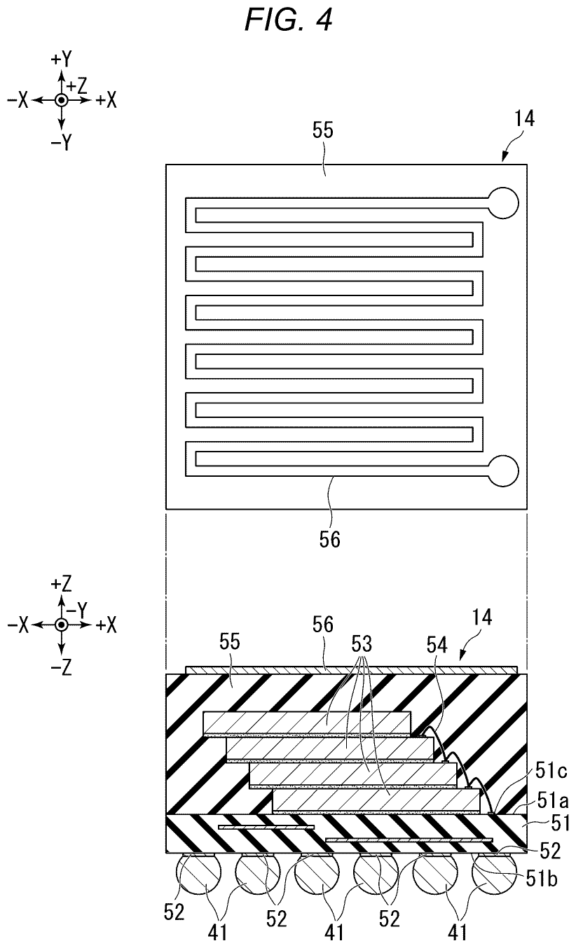

FIG. 4 is a diagram illustrating the NAND package 14. The NAND package 14 includes, for example, a package substrate 51, a plurality of pads 52, a plurality of memory chips 53, a plurality of bonding wires 54 (in FIG. 4, only one bonding wire is illustrated), a sealing member 55, and a heating wiring 56.

The package substrate 51 is a plate-like member in the X and Y directions. The package substrate 51 has a rectangular shape same as the shape of the NAND package 14 when viewed in the Z direction. The package substrate 51 includes a first surface 51a and a second surface 51b located on an opposite side to the first surface 51a. The first surface 51a is a surface facing the +Z direction. The first surface 51a includes a plurality of pads 51c each connected to the bonding wires 54 to be described below. The second surface 51b is a surface facing the-Z direction. The second surface 51b includes a plurality of pads 52.

The solder 41 is provided on the pad 52 and is exposed to outside of the NAND package 14. The solder 41 is an electrical connection portion connected to the pad 31 of the substrate 11. The plurality of solders 41 are disposed, for example, in a lattice arrangement in the X and Y directions. In the present embodiment, the plurality of solders 41 are solder balls of ball grid array (BGA).

The memory chip 53 is, for example, a nonvolatile semiconductor memory chip and is, for example, a NAND flash memory chip. The memory chip 53 includes a plurality of memory cell transistors and peripheral circuits that cause the plurality of memory cell transistors to function as storage elements. The plurality of memory chips 53 are stacked in the Z direction with adhesive films interposed therebetween. The plurality of memory chips 53 are stacked on the first surface 51a of the package substrate 51. The plurality of memory chips 53 are electrically connected to the pad 51c of the package substrate 51 by the bonding wire 54.

The sealing member 55 is an insulating portion that protects the plurality of memory chips 53 and the plurality of bonding wires 54. The sealing member 55 is, for example, mold resin. The sealing member 55 covers the plurality of memory chips 53 and the plurality of bonding wires 54.

The heating wire 56 is a wiring for heating the memory chips 53. The heating wire 56 is provided, for example, on a surface of the sealing member 55. The heating wire 56 is electrically connected to the pad 52 of the NAND package 14 corresponding to the pad 31A of the substrate 11. The heating wire 56 is electrically connected to the power circuit component 15 via the pad 52 of the NAND package 14, the solder 41, the pad 31A of the substrate 11, and the wiring change unit 18A during a heating process of the memory chip 53. During the heating process of the memory chip 53, the heating wire 56 is supplied with power from the power circuit component 15 and generates heat to heat the memory chips 53.

### A4. Wiring Change Unit

### A4.1 State of High-Temperature Reflow

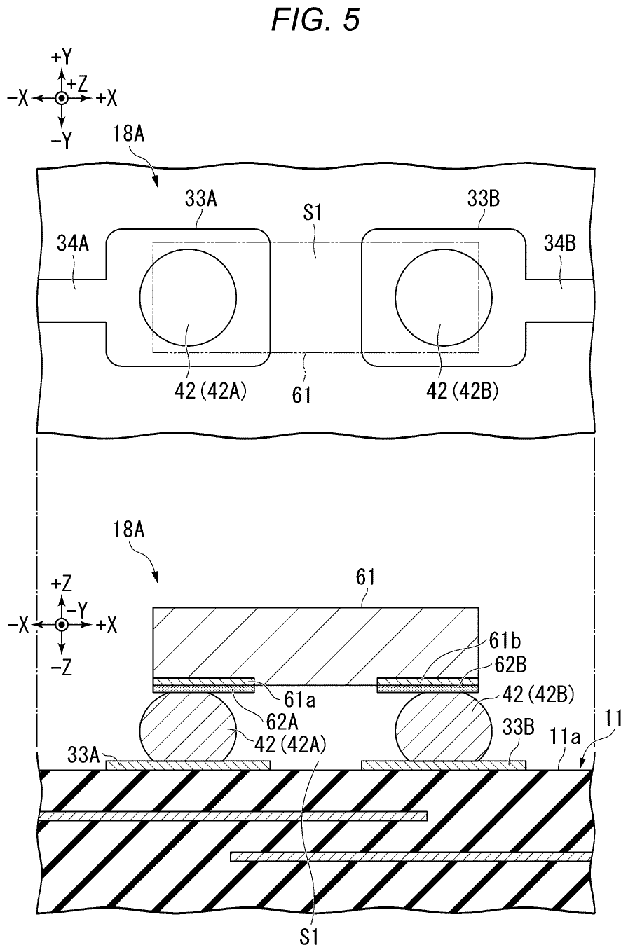

Next, a state of the wiring change unit 18A before a high-temperature reflow will be described. FIG. 5 is a diagram illustrating a state of the wiring change unit 18A before a high-temperature reflow as a secondary reflow. In a state illustrated in FIG. 5, the pads 33A and 33B are electrically insulated, and thus the wiring lines 34A and 34B are in a non-conductive state. “High-temperature reflow” means a reflow process in which the solders 42A and 42B are melted as will be described below.

The wiring change unit 18A includes the solders 42A and 42B, the jumper component 61, and adhesive portions 62A and 62B in addition to the above-described pads 33A and 33B. One or more of the solders 42A and 42B and the jumper component 61 are not essential elements in a state before a high-temperature reflow to be described below. That is, the wiring change unit 18A may be formed only in the pads 33A and 33B in the state of the high-temperature reflow to be described below.

### High-Temperature Solder

The solder 42A is provided on the pad 33A. The solder 42A is in a state before melting. The solder 42A has a shape (may be referred to as “pre-reflow shape”) applied on the pad 33A by screen printing or the like. The solder 42A is disposed in the middle of the pad 33A and is apart from the entire edge of the pad 33A when viewed in the Z direction. The solder 42A is an example of “second solder”.

The solder 42B is provided on the pad 33B. The solder 42B is in a state before melting. The solder 42B has a shape applied on the pad 33B by screen printing or the like. The solder 42B is disposed in the middle of the pad 33B and is apart from the entire edge of the pad 33B when viewed in the Z direction. The solder 42B is an example of “third solder”. In the specification, “second solder” and “third solder” are expressions used for facilitating description. “Second solder” and “third solder” may be the same type of solder or may be different types of solders. In the present embodiment, the solders 42A and 42B are the same type of solder.

Hereinafter, when the solders 42A and 42B are not distinguished from each other, the solders 42A and 42B are simply referred to as “solder 42”. The solder 42 has a different melting point from the solder 41. In the present embodiment, the solder 42 has a higher melting point than the solder 41. For example, the melting point of the solder 42 is higher by 15° C. or more (for example, 20° C. or more) than the melting point of the solder 41. Hereinafter, the solder 42 may be referred to as “high-temperature solder”.

Here, examples of compositions and melting points of solders will be described. For example, representative ingredients and melting points of lead-free solders are as follows.

### Solder Ingredient of First Group (Melting Point of 240° C. or Higher)

First example: Sn (tin) and Sb (antimony)
Second example: Sn (tin) and Cu (copper)
Third example: Sn (tin), Cu (copper), and Ag (silver)
Fourth Example: Sn (tin) and Ag (silver)
   Solder Ingredient of Second Group (Melting Point around 220° C.)
Fifth example: Sn (tin) and Ag (silver)
Sixth example: Sn (tin), Ag (silver), and Cu (copper)
Seventh example: Sn (tin) and Ag (silver)

### Solder Ingredient of Third Group (Melting Point of 200° C. or Lower)

Eighth example: Sn (tin) and Zn (zinc)
Ninth example: Sn (tin), Zn (zinc), and Bi (bismuth)
Tenth example: Sn (tin) and Bi (bismuth)
Eleventh example: Sn (tin) and In (indium)

For example, when the solder 42 (high-temperature solder) is adopted from the first group, the solder 41 (low-temperature solder) is adopted from the second or third group. When the solder 42 (high-temperature solder) is adopted from the second group, the solder 41 (low-temperature solder) is adopted from the third group. Here, compositions of the solders 41 and 42 are not limited to the above examples.

### Jumper Component

Next, the jumper component 61 will be described. The jumper component 61 is a component that electrically connects the pad 33A to the pad 33B when the solder 42 is melted by the high-temperature reflow. The jumper component 61 is, for example, a zero-ohm resistor. The jumper component 61 overlaps the solders 42A and 42B when viewed in the Z direction.

The jumper component 61 includes, for example, a first terminal 61a and a second terminal 61b. The first terminal 61a and the second terminal 61b are electrically connected inside the jumper component 61. The first terminal 61a and the second terminal 61b are exposed in the-Z direction. Each of the first terminal 61a and the second terminal 61b is, for example, a terminal having a plane shape in the X and Y directions. The first terminal 61a overlaps the solder 42A and the pad 33A when viewed in the Z direction. The second terminal 61b overlaps the solder 42B and he pad 33B when viewed in the Z direction.

### First Adhesive Portion

The first adhesive portion 62A is an insulating adhesive provided on a surface of the first terminal 61a of the jumper component 61 in the-Z direction. The first adhesive portion 62A is provided on the entire region of the first terminal 61a of the jumper component 61. The first adhesive portion 62A is disposed between the solder 42A and the first terminal 61a of the jumper component 61 and electrically insulates the first terminal 61a of the jumper component 61 from the solder 42A. The first adhesive portion 62A fixes the first terminal 61a of the jumper component 61 to the solder 42A. The first adhesive portion 62A is formed, for example, by an adhesive that has a higher melting point than the solder 41.

### Second Adhesive Portion

The second adhesive portion 62B is an insulating adhesive provided on a surface of the second terminal 61b of the jumper component 61 in the-Z direction. The second adhesive portion 62B is provided on the entire region of the second terminal 61b of the jumper component 61. The second adhesive portion 62B is disposed between the solder 42B and the second terminal 61b of the jumper component 61 and electrically insulates the second terminal 61b of the jumper component 61 from the solder 42B. The second adhesive portion 62B fixes the second terminal 61b of the jumper component 61 to the solder 42B. The second adhesive portion 62B is formed, for example, by an adhesive that has a higher melting point than the solder 41.

### A4.2 State After High-Temperature Reflow

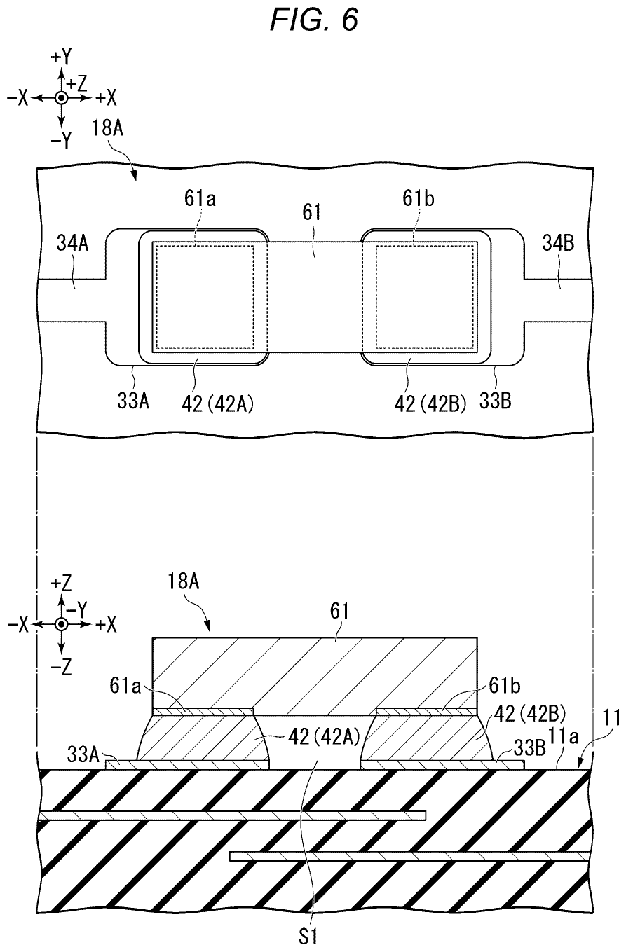

Next, a state of the wiring change unit 18A after the high-temperature reflow will be described. FIG. 6 is a diagram illustrating a state of the wiring change unit 18A after the high-temperature reflow as a secondary reflow. In the state illustrated in FIG. 6, the pads 33A and 33B are electrically connected via the jumper component 61, so that the wiring lines 34A and 34B are in a conductive state. In the state after the high-temperature reflow, the first adhesive portion 62A and the second adhesive portion 62B are melted at a high temperature and lost.

The solder 42A is melted by the high-temperature reflow to have a shape that is wet and spread along a surface of the pad 33A. The solder 42A is in contact with at least a part of the edge of the pad 33A when viewed in the Z direction. The solder 42A is in contact with at least a part of an edge of the first terminal 61a of the jumper component 61 when viewed in the Z direction. In the state after the high-temperature reflow, the first terminal 61a of the jumper component 61 is physically and electrically connected to the pad 33A by the solder 42A.

The solder 42B is melted by the high-temperature reflow to have a shape that is wet and spread along the surface of the pad 33B. The solder 42B is in contact with at least a part of the edge of the pad 33B when viewed in the Z direction. The solder 42B is in contact with at least a part of an edge of the second terminal 61b of the jumper component 61 when viewed in the Z direction. In the state after the high-temperature reflow, the second terminal 61b of the jumper component 61 is physically and electrically connected to the pad 33B by the solder 42B.

When the first terminal 61a of the jumper component 61 is electrically connected to the pad 33A by the solder 42A and the second terminal 61b of the jumper component 61 is electrically connected to the pad 33B by the solder 42B, the pads 33A and 33B are electrically connected. Accordingly, the wiring lines 34A and 34B enter a conductive state, and a heating function of the NAND package 14 can be used.

### A5. Manufacturing Method

Next, a method of manufacturing the storage device 1A will be described.

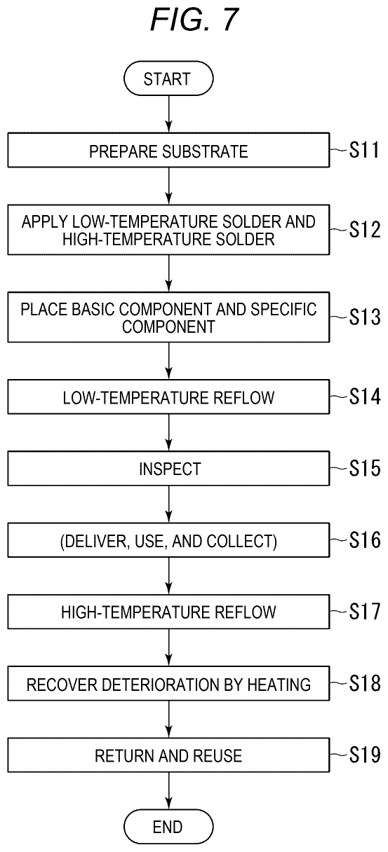

FIG. 7 is a flowchart illustrating the method of manufacturing the storage device 1A. First, the substrate 11 is prepared (S11).

Subsequently, the solders 41 and 42 are supplied to the surface of the substrate 11 (S12). For example, the solder 41 is applied to the pad 32. The solder 42A is applied to the pad 33A. The solder 42B is applied to the pad 33B. The solder 41 connected to the controller 12, the DRAM 13, the NAND package 14, or the power circuit component 15 may be fitted as a solder ball in the controller 12, the DRAM 13, the NAND package 14, or the power circuit component 15.

Subsequently, basic components (for example, the controller 12, the DRAM 13, the NAND package 14, the power circuit component 15, the capacitor 16, and the surface-mounted component 17) and a specific component (for example, the jumper component 61) are placed on the substrate 11 (S13). For example, the jumper component 61 is fixed to the solders 42A and 42B by the first adhesive portion 62A and the second adhesive portion 62B.

Subsequently, the low-temperature reflow as a primary reflow is executed (S14). The low-temperature reflow is a reflow executed at a temperature equal to or higher than the melting point of the solder 41 and lower than the melting point of the solder 42. That is, the low-temperature reflow is a reflow in which the solder 42 does not melt and the solder 41 melts. By executing the low-temperature reflow, the basic components (for example, the controller 12, the DRAM 13, the NAND package 14, the power circuit component 15, the capacitor 16, and the surface-mounted component 17) are physically and electrically connected to the substrate 11 by the solder 41.

Meanwhile, the solder 42 does not melt when the low-temperature reflow is executed. Therefore, the jumper component 61 is maintained in a state fixed to the solder 42 via the first adhesive portion 62A and the second adhesive portion 62B. Therefore, the pads 33A and 33B are electrically insulated, and a non-conductive state in which the wiring lines 34A and 34B are electrically insulated is maintained. Accordingly, the wiring lines 34A and 34B are electrically insulated, and thus the storage device 1A is formed in a first state in which use of the specific function (for example, the heating function of the NAND package 14) of the storage device 1A is limited.

Subsequently, the storage device 1 in the first state is inspected (S15). When there is no problem in the inspection, the storage device 1A in the first state is delivered and used (S16). In the present embodiment, the storage device 1A in which the NAND package 14 is deteriorated, for example, due to use by more than a certain number of writings is collected to recover a deteriorated state of the NAND package 14.

Subsequently, the high-temperature reflow as a secondary reflow is executed on the collected storage device 1A in the first state (S17). The high-temperature reflow is a reflow executed at a temperature equal to or higher than the melting point of the solder 42. By executing the high-temperature reflow, the solder 42 melts, the adhesive portions 62A and 62B are lost, the first terminal 61a of the jumper component 61 is electrically connected to the pad 33A by the solder 42A, and the second terminal 61b of the jumper component 61 is electrically connected to the pad 33B by the solder 42B. Accordingly, the pads 33A and 33B are electrically connected by the jumper component 61. Accordingly, the wiring lines 34A and 34B enter an electrically connected conductive state, and thus the storage device 1A is formed in a second state in which use of the specific function (for example, the heating function of the NAND package 14) of the storage device 1A is allowed.

Subsequently, power is supplied from the power circuit component 15 to the heating wiring 56 of the NAND package 14 and the heating process of the memory chip 53 is executed (S18). That is, the memory chip 53 is heated at a predetermined temperature or higher for a predetermined time. Accordingly, deterioration in the NAND package 14 is recovered. Then, the storage device 1A in which deterioration is recovered is returned to a collecting source to be reused (S19).

The method of manufacturing the storage device 1A is described as an example. Here, a method of manufacturing the storage device 1A is not limited to the above example. For example, the jumper component 61 may be placed on the substrate 11 between the processes of S16 and S17 instead of being placed on the substrate in the process of S13. That is, the storage device 1A in the first state may be used in a state in which the jumper component 61 is not mounted.

The high-temperature reflow as the secondary reflow for changing on and off of the specific function of the storage device 1A may be executed during the manufacturing before delivery of the storage device 1A. That is, when on and off of the specific function of the storage device 1A is desired to be changed during the manufacturing before delivery of the storage device 1A, the high-temperature reflow as the secondary reflow may be executed during the manufacturing before delivery of the storage device 1A. The same content is adopted in second to fourth embodiments.

### A6. Advantages

As a comparative example, a storage device in which melting points of all solders are the same will be considered. In such a configuration, to change an electrical connection state of the wirings later, it is necessary to additionally apply solders when changing the state and/or to execute an additional reflow considering an influence on the state of existing melted solders. Therefore, it is not easy to change the electrical connection state of the wirings later.

Meanwhile, a storage device according to the present embodiment includes a substrate (for example, the substrate 11), a first solder (for example, the solder 41), a first electronic component (for example, the NAND package 14 or the surface-mounted component 17), and a second solder (for example, the solder 42A). The substrate includes a first pad (for example, the pad 31) and a second pad (for example, the pad 32A). The first solder is provided on the first pad. The first electronic component is electrically connected to the first pad by the first solder. At least a part of the second solder is provided on the second pad. The second solder has a different melting point from the first solder. In such a configuration, by properly using a plurality of reflows with different temperatures, it is possible to change the electrical connection state of the wirings later using the solders applied before the primary reflow and/or to change the electrical connection state of the wirings later while reducing influence on a state of the solder melted in the primary reflow. Accordingly, it is possible to provide the storage device in which the electrical connection state of the wirings is easily changeable compared to the comparative example.

In the present embodiment, the second solder has a higher melting point than the first solder. In such a configuration, by properly using a plurality of reflows with different temperatures, it is possible to change the electrical connection state of the wirings later using the high-temperature solders applied before the low-temperature reflow as the primary reflow. Accordingly, it is possible to provide the storage device in which the electrical connection state of the wirings is easily changeable compared to the comparative example.

In the present embodiment, the storage device further includes a second electronic component (for example, the jumper component 61) and a third solder (for example, the solder 42B). The third solder has a different melting point from the first solder. The substrate includes a third pad (for example the pad 33B) in which the third solder is provided. The second electronic component overlaps the second and third solders when viewed in a thickness direction of the substrate. In such a configuration, by melting the second solder later, it is possible to change the electrical connection state of the wirings from a non-conductive state to a conductive state by the second electronic component.

In the present embodiment, the storage device 1A in the state before the secondary reflow further includes a first insulating adhesive portion (for example, the adhesive portion 62A) provided between the first electronic component and the second solder and a second insulating adhesive portion (for example, the adhesive portion 62B) provided between the first electronic component and the third solder. In such a configuration, the second electronic component can be mounted in advance while an insulating property is ensured by the adhesive portions 62A and 62B. For example, by mounting the second electronic component in the same process as the first electronic component, it is possible to achieve improvement in workability of mounting the second electronic component.

In the present embodiment, in the storage device 1A in the state after the secondary reflow, the first electronic component is electrically connected to the second pad by the second solder and is electrically connected to the third pad by the third solder. In such a configuration, by melting the second and third solders later, it is possible to electrically connect the second pad to the third pad.

### Second Embodiment

Next, a second embodiment will be described. The second embodiment is different from the first embodiment in that wirings in a state in which the electronic component is mounted enter a conductive state by a low-temperature reflow and the wirings are changed from the conductive state to a non-conductive state by executing a high-temperature reflow later. Configurations other than those described below are the same as those of the first embodiment.

### B1. Configuration

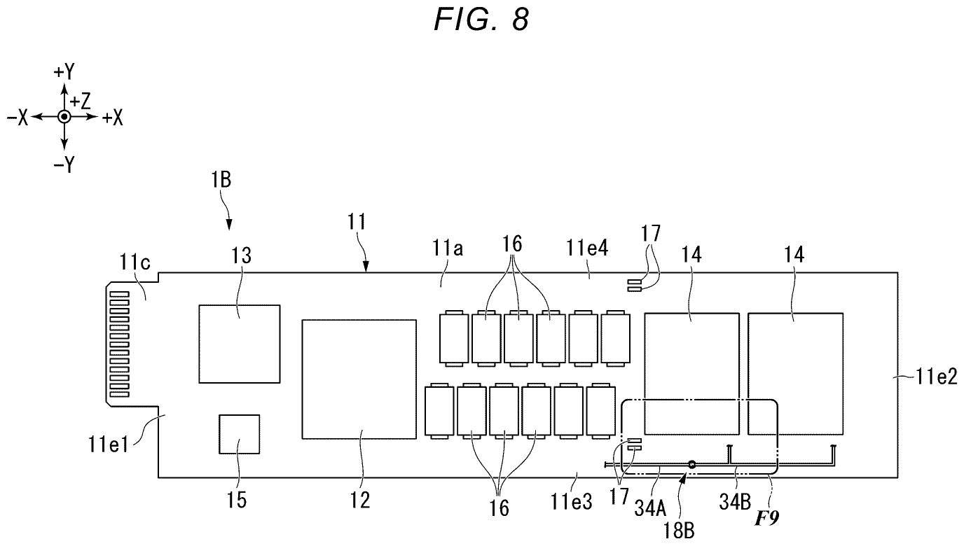

FIG. 8 illustrates a plan view of a storage device 1B according to the second embodiment. The storage device 1B includes a wiring change unit 18B instead of the wiring change unit 18A. The wiring change unit 18B is a functional unit that changes an electrical connection state of a part of the wiring pattern 22 as necessary. For example, the wiring change unit 18B is used to change the electrical connection state of the wiring lines 34A and 34B from a conductive state to a non-conductive state. In the present embodiment, the wiring change unit 18B is used to change a specific function of the storage device 1B. Hereinafter, an example in which on and off of a heating function of the NAND package 14 is changed by electrically connecting the wiring change unit 18B to the NAND package 14 will be described. As in the first embodiment, the specific function is not limited to the heating function.

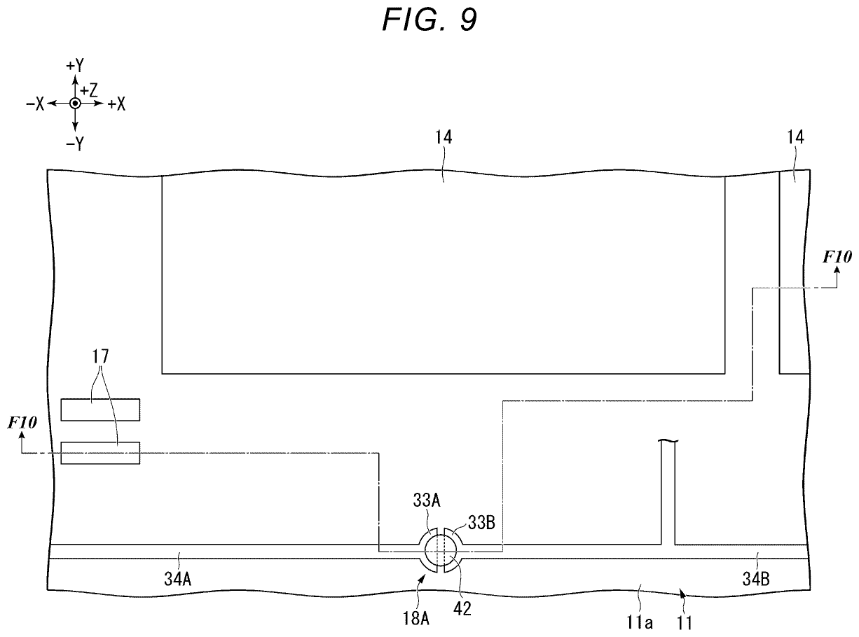

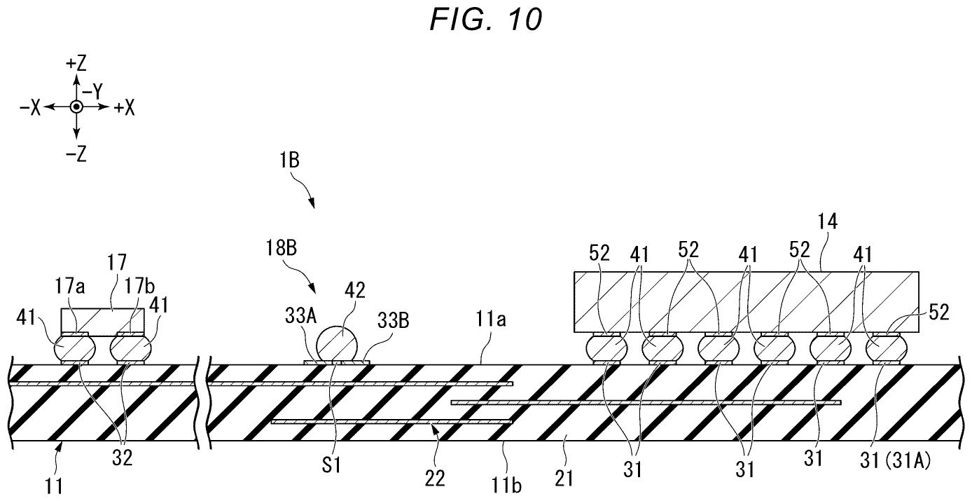

FIG. 9 illustrates an enlarged plan view of a portion surrounded by F9 in the configuration illustrated in FIG. 8. FIG. 10 illustrates a cross-sectional view taken along a line F10-F10 in the configuration illustrated in FIG. 9. In the present embodiment, a basic component (for example, the NAND package 14 or the surface-mounted component 17) is physically and electrically connected to the pad 31 of the substrate 11 by the solder 41.

In the present embodiment, the wiring change unit 18B includes the solder 42 in addition to the pads 33A and 33B. The pad 33B is disposed near the pad 33A with a gap S1 interposed therebetween and is electrically separated (that is, electrically insulated) from the pads 32. In the present embodiment, the pad 33A has a semicircular shape along a part of an outer circumference of the circular solder 42 when viewed in the Z direction. Similarly, the pad 33B has a semicircular shape along another part of the outer circumference of the circular solder 42 when viewed in the Z direction. That is, one circular pad along the outer circumference of the solder 42 is formed by the pads 33A and 33B. The pad 33A is an example of “second pad”. The pad 33B is an example of “third pad”.

In the present embodiment, the solder 42 is provided on the pads 33A and 33B. For example, a part of the solder 42 is provided on the pad 33A. Another part of the solder 42 is provided on the pad 33B. The solder 42 is provided across the pads 33A and 33B. In the present embodiment, the solder 42 has a higher melting point than the solder 41. For example, the melting point of the solder 42 is higher by 15° C. or more (for example, 20° C. or more) than the melting point of the solder 41.

### State Before High-Temperature Reflow

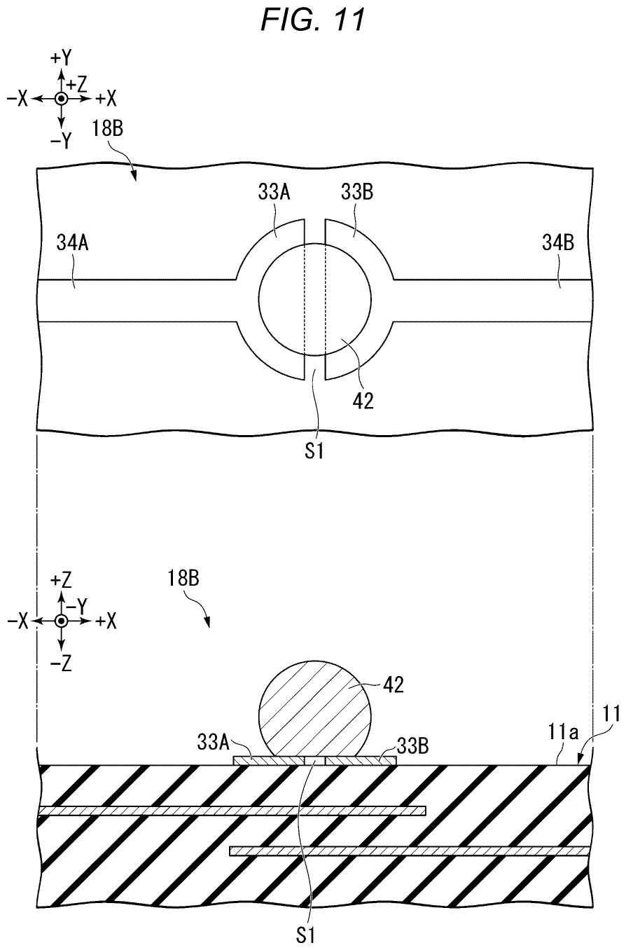

Next, a state of the wiring change unit 18B before a high-temperature reflow will be described. FIG. 11 is a diagram illustrating a state of the wiring change unit 18B before a high-temperature reflow as a secondary reflow. In a state illustrated in FIG. 11, the solder 42 is provided across the pads 33A and 33B without being melted. The solder 42 is physically and electrically connected to the pad 33A and is physically and electrically connected to the pad 33B. The solder 42 electrically connects the pad 33A to the pad 33B. Accordingly, the storage device 1B is in a conductive state in which the wiring line 34A and the wiring line 34B are electrically connected.

### State After High-Temperature Reflow

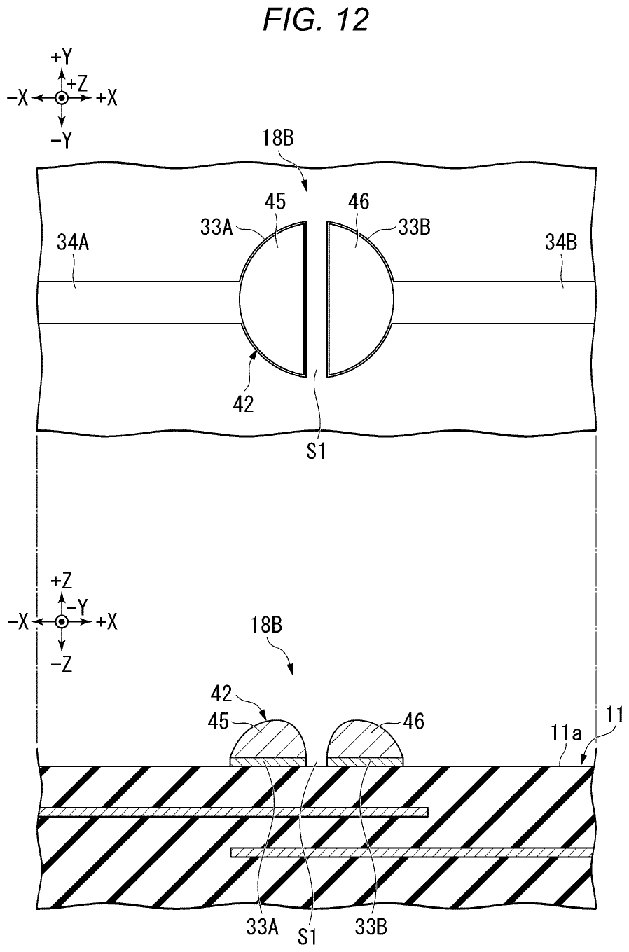

Next, a state of the wiring change unit 18B after the high-temperature reflow will be described. FIG. 12 is a diagram illustrating a state of the wiring change unit 18B after the high-temperature reflow as a secondary reflow. In the state illustrated in FIG. 12, the solder 42 is melted once by the high-temperature reflow and is wetted and spread separately in the pads 33A and 33B. The solder 42 includes a first portion 45 and a second portion 46.

The first portion 45 of the solder 42 has a shape wetted and spread along the surface of the pad 33A. The first portion 45 of the solder 42 is in contact with at least a part of the edge of the pad 33A when viewed in the Z direction.

The second portion 46 of the solder 42 is separated from the first portion 45 of the solder 42. The second portion 46 of the solder 42 has a shape wetted and spread along the surface of the pad 33B. The second portion 46 of the solder 42 is in contact with at least a part of the edge of the pad 33B when viewed in the Z direction.

In the state illustrated in FIG. 12, the pad 33A is electrically insulated from the pad 33B. Accordingly, the storage device 1B is in a non-conductive state in which the wiring line 34A is electrically insulated from the wiring line 34B.

### B2. Manufacturing Method

Next, a method of manufacturing the storage device 1B will be described.

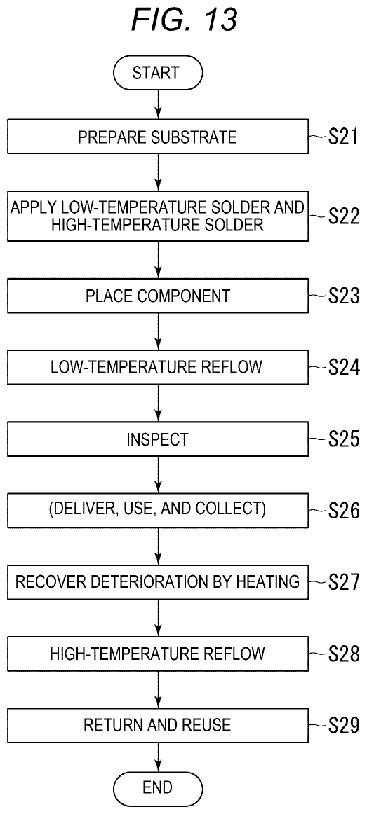

FIG. 13 is a flowchart illustrating a method of manufacturing the storage device 1B. First, the substrate 11 is prepared (S21).

Subsequently, the solders 41 and 42 are applied to the surface of the substrate 11 (S22). For example, the solder 41 is applied to the pad 32. The solder 42 is applied across the pads 33A and 33B. The solder 41 connected to the controller 12, the DRAM 13, the NAND package 14, or the power circuit component 15 may be fitted as a solder ball in the controller 12, the DRAM 13, the NAND package 14, or the power circuit component 15. Subsequently, various components (for example, the controller 12, the DRAM 13, the NAND package 14, the power circuit component 15, the capacitor 16, and the surface-mounted component 17) are placed on the substrate 11 (S23).

Subsequently, the low-temperature reflow as a primary reflow is executed (S24). By executing the low-temperature reflow, various components (for example, the controller 12, the DRAM 13, the NAND package 14, the power circuit component 15, the capacitor 16, and the surface-mounted component 17) are physically and electrically connected to the substrate 11 by the solder 41.

Meanwhile, even when the low-temperature reflow is executed, the solder 42 does not melt. Therefore, the solder 42 provided across the pads 33A and 33B is maintained. Accordingly, the wiring lines 34A and 34B are electrically connected, and thus the storage device 1B is formed in a first state in which use of the specific function (for example, the heating function of the NAND package 14) of the storage device 1B is allowed.

Subsequently, the storage device 1B in the first state is inspected (S25). When there is no problem in the inspection, the storage device 1B in the first state is delivered and used (S26). In the present embodiment, the storage device 1B in which the NAND package 14 is deteriorated, for example, due to use by more than a certain number of writings is collected to recover a deteriorated state of the NAND package 14.

Subsequently, in the collected storage device 1B in the first state, power is supplied from the power circuit component 15 to the heating wiring 56 of the NAND package 14 and the heating process of the memory chip 53 is executed (S27). That is, the memory chip 53 is heated at a predetermined temperature or higher for a predetermined time. Accordingly, deterioration in the NAND package 14 is recovered.

Subsequently, the high-temperature reflow as the secondary reflow is executed (S28). The pad 33A is electrically insulated from the pad 33B by melting the solder 42 by the high-temperature reflow and separating the first portion 45 from the second portion 46. Accordingly, the wiring lines 34A and 34B are electrically insulated, and thus the storage device 1B is formed in a second state in which use of the specific function (for example, the heating function of the NAND package 14) of the storage device 1B is limited. In the storage device 1B in the second state, a re-heating process is reliably prevented, and thus it is possible to achieve improvement in reliability of the storage device 1B. The storage device 1B in which deterioration is recovered is returned to a collecting source to be reused (S29).

### B3. Advantages

In the present embodiment, a substrate (for example, the substrate 11) includes a third pad (for example, the pad 33B) disposed near a second pad (for example, the pad 33A) with a gap (for example, the gap S1) interposed with the second pad. The second solder is provided on the second and third pads. In such a configuration, by melting the second solder later, it is possible to change the electrical connection state of the wirings from a conductive state to a non-conductive state.

In the present embodiment, the second solder is provided across the second and third pads and electrically connects the second pad to the third pad. In such a configuration, a conductive state in which the second pad is electrically connected to the third pad can be implemented by the second solder applied before the primary reflow.

In the present embodiment, the second solder includes a first portion (for example, the first portion 45) provided on the second pad and a second portion (for example, the second portion 46) separated from the first portion and provided on the third pad. In such a configuration, the second and third pads can be electrically insulated from each other by the secondary reflow executed later.

### Third Embodiment

Next, a third embodiment will be described. The third embodiment is different from the first embodiment in that a basic component is connected by a high-temperature reflow as a primary reflow and wirings are changed from a non-conductive state to a conductive state by a low-temperature reflow as a secondary reflow. Configurations other than those described below are the same as those of the first embodiment.

### C1. Configuration

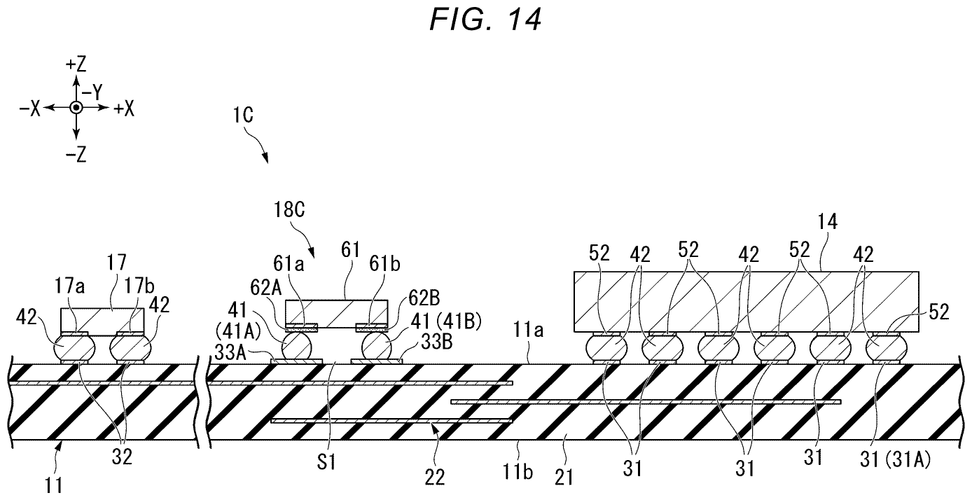

FIG. 14 illustrates a cross-sectional view of a storage device 1C according to the third embodiment. FIG. 14 illustrates a state before the low-temperature reflow as the secondary reflow. In the state illustrated in FIG. 14, the storage device 1C is in a non-conductive state in which the pad 33A is electrically insulated from the pad 33B, and the wiring line 34A is electrically insulated from the wiring line 34B.

In the present embodiment, a basic component (for example, the NAND package 14 or the surface-mounted component 17) is physically and electrically connected to the pad 31 of the substrate 11 by the solder 42 that is a high-temperature solder. In the present embodiment, the solder 42 is an example of “first solder”.

The storage device 1C includes a wiring change unit 18C instead of the wiring change unit 18A. The wiring change unit 18C is a functional unit that changes an electrical connection state of a part of the wiring pattern 22 as necessary. For example, the wiring change unit 18C is used to change the electrical connection state of the wiring lines 34A and 34B from a conductive state to a non-conductive state. The wiring change unit 18C is used to change a specific function of the storage device 1C. Hereinafter, an example in which on and off of a heating function of the NAND package 14 is changed by electrically connecting the wiring change unit 18C to the NAND package 14 will be described. As in the first embodiment, the specific function is not limited to the heating function.

In the present embodiment, the wiring change unit 18C includes solders 41A and 41B, the jumper component 61, and the adhesive portions 62A and 62B in addition to the above-described pads 33A and 33B. One or more of the solders 41A and 41B and the jumper component 61 are not essential elements in a state before a high-temperature reflow to be described below. That is, the wiring change unit 18C may be formed only in the pads 33A and 33B in the state of the high-temperature reflow.

The solder 41A is provided on the pad 33A. The solder 41A is in a state before melting. The solder 41A has a shape applied on the pad 33A by screen printing or the like. The solder 41A is disposed in the middle of the pad 33A and is apart from the entire edge of the pad 33A when viewed in the Z direction. The solder 41A is an example of “second solder”.

The solder 41B is provided on the pad 33B. The solder 41B is in a state before melting. The solder 41B has a shape applied on the pad 33B by screen printing or the like. The solder 41B is disposed in the middle of the pad 33B and is apart from the entire edge of the pad 33B when viewed in the Z direction. The solder 41B is an example of “third solder”. In the specification, “second solder” and “third solder” are expressions used for facilitating description. “Second solder” and “third solder” may be the same type of solder or may be different types of solders. For example, the solders 41A and 41B are the same type of solder.

Hereinafter, when the solders 41A and 41B are not distinguished from each other, the solders 41A and 41B are simply referred to as “solder 41”. In the present embodiment, the solder 41 has a lower melting point than the solder 42. For example, the melting point of the solder 41 is lower by 15° C. or more (for example, 20° C. or more) than the melting point of the solder 42.

When the solder 41 is melted by the low-temperature reflow as the secondary reflow, the jumper component 61 is electrically connected to the pads 33A and 33B and electrically connects the pad 33A to the pad 33B.

The first adhesive portion 62A is disposed between the solder 41A and the first terminal 61a of the jumper component 61 and electrically insulates the solder 41A from the first terminal 61a of the jumper component 61. The first adhesive portion 62A fixes the first terminal 61a of the jumper component 61 to the solder 41A.

The second adhesive portion 62B is disposed between the solder 41B and the second terminal 61b of the jumper component 61 and electrically insulates the solder 41B from the second terminal 61b of the jumper component 61. The second adhesive portion 62B fixes the second terminal 61b of the jumper component 61 to the solder 41B.

### C2. Manufacturing Method

Next, a method of manufacturing the storage device 1C will be described.

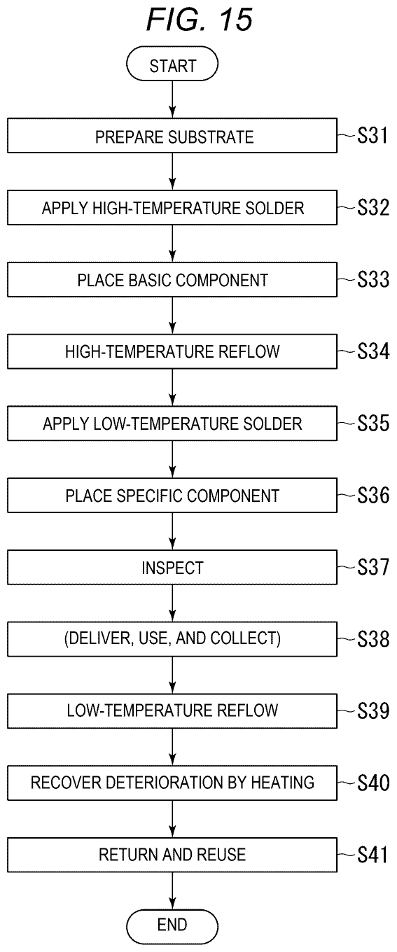

FIG. 15 is a flowchart illustrating a method of manufacturing the storage device 1C. First, the substrate 11 is prepared (S31).

Subsequently, the solder 42 is applied to the surface of the substrate 11 (S32). For example, the solder 42 is applied to the pad 32. The solder 42 connected to the controller 12, the DRAM 13, the NAND package 14, or the power circuit component 15 may be fitted as a solder ball in the controller 12, the DRAM 13, the NAND package 14, or the power circuit component 15.

Subsequently, basic components (for example, the controller 12, the DRAM 13, the NAND package 14, the power circuit component 15, the capacitor 16, and the surface-mounted component 17) are placed on the substrate 11 (S33). Subsequently, the high-temperature reflow as a primary reflow is executed (S34). By executing the high-temperature reflow, the basic components (for example, the controller 12, the DRAM 13, the NAND package 14, the power circuit component 15, the capacitor 16, and the surface-mounted component 17) are physically and electrically connected to the substrate 11 by the solder 42.

Subsequently, the solder 41 is applied to the surface of the substrate 11 (S35). For example, the solder 41A is applied to the pad 33A. The solder 41B is applied to the pad 33B. Subsequently, a specific component (for example, the jumper component 61) is placed on the substrate 11 (S36). For example, the jumper component 61 is fixed to the solders 41A and 41B by the first adhesive portion 62A and the second adhesive portion 62B. Accordingly, the wiring lines 34A and 34B are electrically insulated, and thus the storage device 1C is formed in a first state in which use of the specific function (for example, the heating function of the NAND package 14) of the storage device 1C is limited.

Subsequently, the storage device 1C in the first state is inspected (S37). When there is no problem in the inspection, the storage device 1C in the first state is delivered and used (S38). In the present embodiment, the storage device 1C in which the NAND package 14 is deteriorated, for example, due to use by more than a certain number of writings is collected to recover a deteriorated state of the NAND package 14.

Subsequently, in the collected storage device 1C in the first state, the low-temperature reflow as the secondary reflow is executed (S39). The low-temperature reflow is a reflow executed at a temperature equal to or higher than the melting point of the solder 41 and lower than the melting point of the solder 42. By executing the low-temperature reflow, the solder 41 melts without melting the solder 42, the adhesive portions 62A and 62B are lost, the first terminal 61a of the jumper component 61 is electrically connected to the pad 33A by the solder 41A, and the second terminal 61b of the jumper component 61 is electrically connected to the pad 33B by the solder 41B. Accordingly, the pad 33A is electrically connected to the pad 33B by the jumper component 61. Accordingly, the wiring lines 34A and 34B enter an electrically connected conductive state, and thus the storage device 1C is formed in a second state in which use of the specific function (for example, the heating function of the NAND package 14) of the storage device 1C is allowed.

Subsequently, power is supplied from the power circuit component 15 to the heating wiring 56 of the NAND package 14 and a heating process of the memory chip 53 is executed (S40). That is, the memory chip 53 is heated at a predetermined temperature or higher for a predetermined time. Accordingly, deterioration in the NAND package 14 is recovered. Then, the storage device 1C in which deterioration is recovered is returned to a collecting source to be reused (S41).

The method of manufacturing the storage device 1C is described as an example. Here, the method of manufacturing the storage device 1C is not limited to the above example. For example, the jumper component 61 may be placed on the substrate 11 between the processes of S38 and S39 instead of being placed on the substrate in the process of S36. That is, the storage device 1C in the first state may be used in a state in which the jumper component 61 is not mounted.

The solder 41 may be applied to the substrate 11 between the processes of S38 and S39 instead of being applied to the substrate 11 in the process of S35. That is, the storage device 1C in the first state may be used in a state in which the solder 41 and the jumper component 61 are not provided.

### C3. Advantages

In the present embodiment, the second solder has a lower melting point than the second solder. In such a configuration, by properly using a plurality of reflows with different temperatures, it is possible to change the electrical connection state of the wirings later by the secondary reflow while reducing influence on a state of the solder (that is, solder melted by the primary reflow) connecting the basic component. Accordingly, the electrical connection state of the wirings is easily changeable compared to the comparative example.

### Fourth Embodiment

Next, a fourth embodiment will be described. The fourth embodiment is different from the third embodiment in that a basic component is connected by a high-temperature reflow as a primary reflow and wirings are changed from the conductive state to a non-conductive state by a low-temperature reflow as a secondary reflow. Configurations other than those described below are the same as those of the third embodiment.

### D1. Configuration

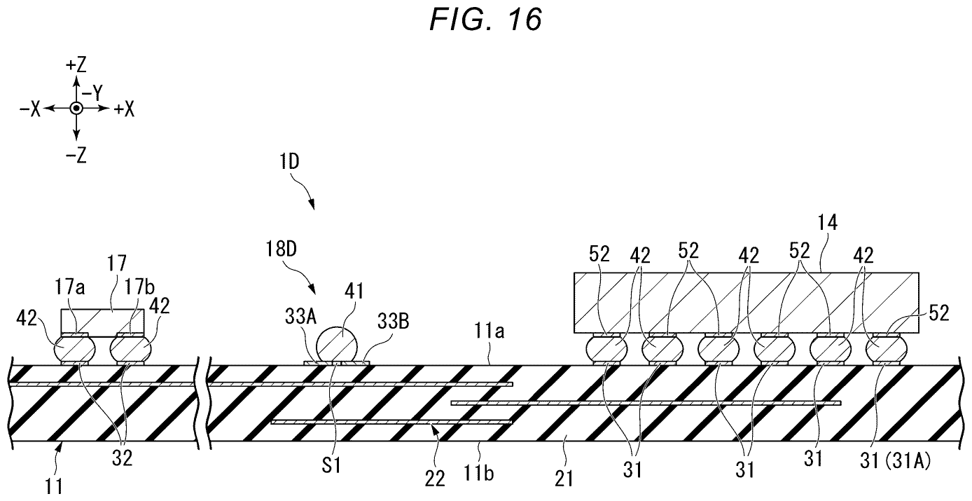

FIG. 16 illustrates a cross-sectional view of a storage device 1D according to the fourth embodiment. FIG. 16 illustrates a state before the low-temperature reflow as a secondary reflow. In the state illustrated in FIG. 16, the storage device 1D is in a conductive state in which the pads 33A and 33B are electrically connected and the wiring lines 34A and 34B are electrically connected.

The storage device 1D includes a wiring change unit 18D instead of the wiring change unit 18C. The wiring change unit 18D is a functional unit that changes an electrical connection state of a part of the wiring pattern 22 as necessary. For example, the wiring change unit 18D is used to change the electrical connection state of the wiring lines 34A and 34B from a conductive state to a non-conductive state. The wiring change unit 18D is used to change a specific function of the storage device 1D. Hereinafter, an example in which on and off of a heating function of the NAND package 14 is changed by electrically connecting the wiring change unit 18D to the NAND package 14 will be described. As in the first embodiment, the specific function is not limited to the heating function.

In the present embodiment, the solder 41 that is a low-temperature solder is provided on the pads 33A and 33B. For example, a part of the solder 41 is provided on the pad 33A. Another part of the solder 41 is provided on the pad 33B. The solder 41 is provided across the pads 33A and 33B. The solder 41 electrically connects the pad 33A to the pad 33B and electrically connects the wiring line 34A to the wiring line 34B. The solder 41 is an example of “second solder”. The solder 42 is an example of “first solder”.

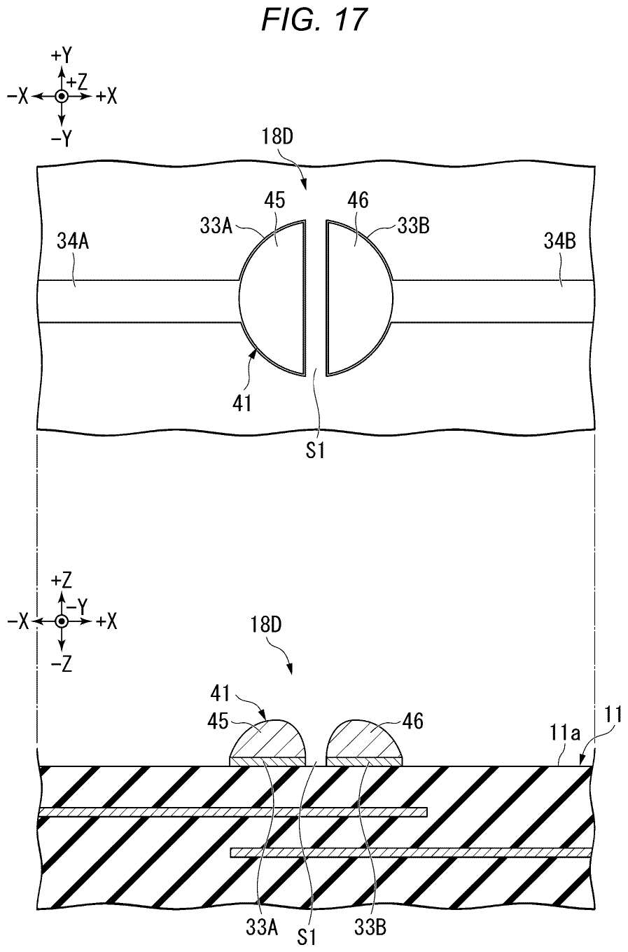

FIG. 17 is a diagram illustrating a state of the wiring change unit 18D after a low-temperature reflow as the secondary reflow. In the state illustrated in FIG. 17, the solder 41 is melted once by the high-temperature reflow and is wetted and spread separately in the pads 33A and 33B. The solder 41 includes the first portion 45 and the second portion 46.

The first portion 45 of the solder 41 has a shape that is wet and spread along the surface of the pad 33A. The first portion 45 of the solder 41 is in contact with at least a part of the edge of the pad 33A when viewed in the Z direction.

The second portion 46 of the solder 41 is separated from the first portion 45 of the solder 41. The second portion 46 of the solder 41 has a shape that is wet and spread along the surface of the pad 33B. The second portion 46 of the solder 41 is in contact with at least a part of the edge of the pad 33B when viewed in the Z direction.

In the state illustrated in FIG. 17, the pad 33A is electrically insulated from the pad 33B. Accordingly, the storage device 1D is in a non-conductive state in which the wiring line 34A is electrically insulated from the wiring line 34B.

### D2. Manufacturing Method

Next, a method of manufacturing the storage device 1D will be described.

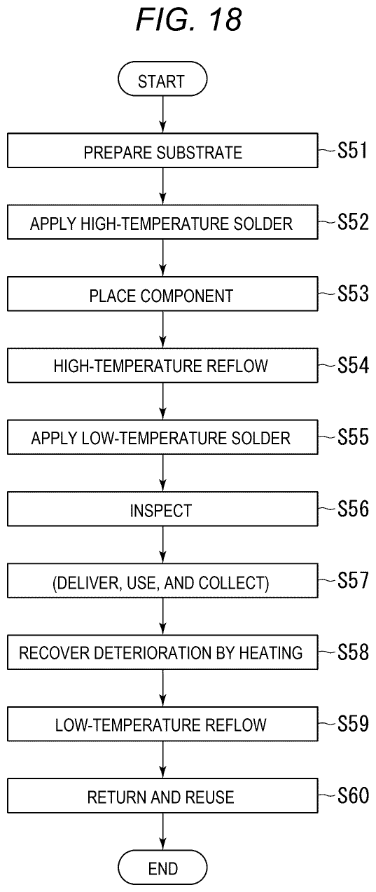

FIG. 18 is a flowchart illustrating the method of manufacturing the storage device 1D. First, the substrate 11 is prepared (S51).

Subsequently, the solder 42 is applied to the surface of the substrate 11 (S52). For example, the solder 42 is applied to the pad 32. The solder 42 connected to the controller 12, the DRAM 13, the NAND package 14, or the power circuit component 15 may be fitted as a solder ball in the controller 12, the DRAM 13, the NAND package 14, or the power circuit component 15.

Subsequently, various components (for example, the controller 12, the DRAM 13, the NAND package 14, the power circuit component 15, the capacitor 16, and the surface-mounted component 17) are placed on the substrate 11 (S53). Subsequently, the high-temperature reflow as a primary reflow is executed (S54). By executing the high-temperature reflow, various components (for example, the controller 12, the DRAM 13, the NAND package 14, the power circuit component 15, the capacitor 16, and the surface-mounted component 17) are physically and electrically connected to the substrate 11 by the solder 42.

Subsequently, the solder 41 is applied on the surface of the substrate 11 (S55). For example, the solder 41 is applied across the pads 33A and 33B. Accordingly, the wiring lines 34A and 34B are electrically connected, and thus the storage device 1D is formed in a first state in which use of the specific function (for example, the heating function of the NAND package 14) of the storage device 1D is allowed.

Subsequently, the storage device 1D in the first state is inspected (S56). When there is no problem in the inspection, the storage device 1D in the first state is delivered and used (S57). In the present embodiment, the storage device 1D in which the NAND package 14 is deteriorated, for example, due to use by more than a certain number of writings is collected to recover a deteriorated state of the NAND package 14.

Subsequently, in the collected storage device 1D in the first state, power is supplied from the power circuit component 15 to the heating wiring 56 of the NAND package 14 and a heating process of the memory chip 53 is executed (S58). That is, the memory chip 53 is heated at a predetermined temperature or higher for a predetermined time. Accordingly, deterioration in the NAND package 14 is recovered.

Subsequently, the low-temperature reflow as a secondary reflow is executed (S59). The low-temperature reflow is a reflow executed at a temperature equal to or higher than the melting point of the solder 41 and lower than the melting point of the solder 42. The pad 33A is electrically insulated from the pad 33B by melting the solder 41 by the low-temperature reflow and separating the first portion 45 from the second portion 46 while the solder 42 is not melted. Accordingly, the wiring lines 34A and 34B are electrically insulated, and thus the storage device 1D is formed in a second state in which use of the specific function (for example, the heating function of the NAND package 14) of the storage device 1D is limited. In the storage device 1D in the second state, a re-heating process is reliably prevented, and thus it is possible to achieve improvement in reliability of the storage device 1D. Then, the storage device 1D in which deterioration is recovered is returned to a collecting source to be reused (S60).

### D3. Advantages

In the present embodiment, the second solder has a lower melting point than the first solder. In such a configuration, by properly using a plurality of reflows with different temperatures, it is possible to change the electrical connection state of the wirings later by the secondary reflow while reducing influence on a state of the solder (that is, solder melted by the primary reflow) connecting the basic component. Accordingly, the electrical connection state of the wirings is easily changeable compared to the comparative example.

Several embodiments are described above. Here, embodiments and modifications are not limited to the above-described examples. For example, in the second and fourth embodiments, shapes of the pads 33A and 33B are not limited to the semicircular shape, and may be a rectangular shape or other shapes.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A storage device comprising:
a substrate including a first pad and a second pad;
a first solder provided on the first pad;
a first electronic component electrically connected to the first pad via the first solder; and
a second solder at least a part of which is provided on the second pad, the second solder having a different melting point from the first solder.

2. The storage device according to claim 1, wherein the second solder has a higher melting point than the first solder.

3. The storage device according to claim 1, wherein the second solder has a lower melting point than the first solder.

4. The storage device according to claim 1, further comprising:
a second electronic component; and
a third solder having a different melting point from the first solder, wherein
the substrate includes a third pad on which the third solder is provided, and
the second electronic component overlaps the second solder and the third solder when viewed in a thickness direction of the substrate.

5. The storage device according to claim 4, further comprising:
a first insulating adhesive portion provided between the second electronic component and the second solder; and
a second insulating adhesive portion provided between the second electronic component and the third solder.

6. The storage device according to claim 5, wherein the second solder and the third solder are electrically separated from each other.

7. The storage device according to claim 5, wherein the first solder has a post-reflow shape, and the second solder and the third solder each have a pre-reflow shape.

8. The storage device according to claim 4, wherein the second solder and the third solder are electrically connected via the second electronic component.

9. The storage device according to claim 8, wherein the first solder, the second solder, and the third solder each have a pre-reflow shape.

10. The storage device according to claim 4, wherein the third solder has a same melting point as the second solder.

11. The storage device according to claim 4, wherein
the first electric component is a semiconductor package including a semiconductor chip, and
the second electric component is a zero-ohm resistor.

12. The storage device according to claim 11, wherein the semiconductor package comprises a plurality of nonvolatile semiconductor memory chips and a heating wire.

13. The storage device according to claim 1, wherein
the substrate includes a third pad disposed adjacent to the second pad with a gap with the second pad, and
the second solder is provided on the second pad and the third pad.

14. The storage device according to claim 13, wherein the second solder is provided across the second pad and the third pad and electrically connects the second pad and the third pad.

15. The storage device according to claim 13, wherein the first solder has a post-reflow shape, and the second solder has a pre-reflow shape.

16. The storage device according to claim 13, wherein the second solder includes a first portion provided on the second pad and a second portion provided on the third pad and separated from the first portion.

17. The storage device according to claim 13, wherein the second pad and the third pad are electrically separated from each other.

18. The storage device according to claim 13, wherein the first portion and the second portion each have a post-reflow shape.

19. The storage device according to claim 13, wherein the first electric component is a semiconductor package that includes a plurality of nonvolatile semiconductor memory chips and a heating wire.

20. A method of manufacturing a storage device, the method comprising:
preparing a substrate including a first pad and a second pad;
forming a first solder on the first pad;
forming a second solder, at least a part of which being on the second pad, the second solder having a different melting point from the first solder; and
electrically connecting a first electronic component to the first pad.
